(19) United States
(12) Patent Application Publication
(10) Pub. No.: US 2023/0413465 A1
(43) Pub. Date: Dec. 21, 2023

(54) A MODULAR ELECTRONICS ASSEMBLY

(71) Applicant: Tritium Holdings Pty Ltd, Murarrie (AU)

(72) Inventors: Bernard Brian WALSH, Brisbane (AU); Michael John WALTON, Brisbane (AU); Gareth James TAYLOR, Brisbane (AU); Shelley Ellen FARRELL, Brisbane (AU); Nicholas Athol KEELING, Brisbane (AU); Aaron Jarvis PALM, Brisbane (AU); David Andrew FINN, Brisbane (AU); James McFarlane KENNEDY, Brisbane (AU)

(21) Appl. No.: 18/037,193

(22) PCT Filed: Nov. 17, 2021
(86) PCT No.: PCT/AU2021/051364

§ 371 Date: May 16, 2023

(30) Foreign Application Priority Data
Nov. 17, 2020 (AU) 2020904242

(51) Int. Cl. H05K 7/02; H05K 7/20; H05K 7/14; B60L 53/16; B60L 53/18

(52) U.S. Cl. CPC H05K 7/023; H05K 7/20218; H05K 7/1454; B60L 53/16; B60L 53/18; H05K 7/20927

(57) ABSTRACT

A modular electronics assembly comprising: removable electronic modules comprising a module housing containing electronic circuitry and bearing a module electrical connector coupled to the electronic circuitry each removable electronic module having a first alignment formation; an enclosure having an interior dimensioned to contain the removable electronic modules therein, the enclosure including, one or more enclosure electrical connectors corresponding to one or more of the module electrical connectors for establishing a connection, guide members extending into the interior of the enclosure for guiding respective ones of the module housings toward the enclosure electrical connectors; second alignment formations each arranged to cooperate with a respective first alignment formation of the removable electronic modules for aligning module electrical connectors with enclosure electrical connectors to thereby establish connection; wherein the first alignment formations are positioned on the module housings to register with respective second alignment formations upon the module housings abutting respective guide members.

### RELATED APPLICATIONS

The present application claims priority from Australian provisional patent application No. 2020904242, filed 17 Nov. 2020, the content of which is hereby incorporated herein in its entirety.

### TECHNICAL FIELD

The present invention relates to a modular electronics assembly that includes removable electronic modules. The present invention particularly relates to a modular electronics assembly that includes an alignment arrangement for facilitating the establishment of connections between connectors of the removable electronic modules and corresponding connectors of an enclosure of the assembly.

### BACKGROUND

Any references to methods, apparatus or documents of the prior art are not to be taken as constituting any evidence or admission that they formed, or form part of the common general knowledge.

The present invention concerns modular electronics assemblies of which power electronics assemblies are one example. Power electronics assemblies convert and control electrical power so that an input power of a certain voltage, AC/DC characteristic and current range can be converted into an output power source that meets the power supply requirements of a target electronic system.

One example of a power electronics assembly is an electric vehicle charger. In recent years battery powered electric vehicles have become increasingly prevalent. It is expected that the use of electric vehicles will continue to increase in coming years as the global economy transitions from being fossil fuel based to widespread use of renewable power. Electric vehicles require recharging stations throughout road networks in order that they can be recharged along their journeys.

The recharging stations include a number of electric vehicle (EV) chargers which convert AC power to a controlled and metered source of DC current that is suitable for recharging the batteries of electric vehicles.

Early generation EV chargers, contain an interconnected array of circuit boards, cooling pipes, harnesses, and power cables, that cannot be easily separated after assembly. Grid power enters such a charger through input filters and a circuit breaker. If failure occurs in this area, the whole circuit board must be removed by undoing numerous nuts and harnesses.

The power conversion and isolation electronics are too large and heavy to remove in the field. Thus, if these components fail and service is required, the entire assembly must be transported back to a repair facility, which may entail global shipping. This transportation process is particularly necessary as the power conversion and isolation electronics are attached to a metal water block which cannot easily be removed in the field. Additionally, any component which is directly attached to a water block is at risk of being destroyed if removal of a block is attempted.

Furthermore, there are over 100 meters of harnesses and power cables attached to the power conversion electronics that would have to be disconnected for the electronics to be removed.

Due to the complexities and dangers inherent in disconnecting harnesses and cables, and in working with delicate electrical components, only a skilled technician can perform a field service on the components of typical early generation EV chargers excluding the power conversion and isolation electronics. The complexities of service are demanding on time. Employing and training skilled technicians who would be required to work for considerable time in the field is very costly. The alternative of returning a charger to the manufacturing facility for the repair of non-power conversion and isolation electronics is time-consuming, extremely costly, and detrimental to EV operators, who would then be left without a charger. Hence, servicing individual components of early generation EV chargers is generally a complex, expensive and time-intensive process.

As a response to the time-consuming nature of servicing first generation EV chargers it has been known to provide modular EV charger designs in recent years. The transition from non-modular (planar) to modular EV charging systems provides benefits for operators of EV chargers. These benefits include the ability for EV charger operators to replace modules containing older and less power efficient electronics (e.g. inverters) with newer and more efficient variants without the requirement of purchasing whole new EV charging units. The advantages also include the ability for operators to replace malfunctioning electronics by switching modules instead of exchanging entire charging units.

Furthermore, the levels of power distribution per charger can be altered after installation, in accordance with operators' business requirements, without necessitating the replacement of whole chargers. For example, modules may be exchanged in order to replace an existing module with a replacement module that has upgraded power handling capability, improved performance characteristics and/or other operational features. Any efficiency gains incurred by operators of EV chargers are likely to be passed onto consumer and commercial owners of EVs by lowering the costs of charging, with the consequent result being that barriers preventing entry into the EV market, and the use of EVs in general, are further removed.

However, most electronics in modular EV charger designs reside within modules that are interconnected via cables or in some designs via backplanes that bear power and/or data connectors.

Power and/or data connectors that connect to modules through backplanes risk bearing modules' weights should misalignment of the connectors occur when establishing a connection. As a result, following service, the power and/or data connectors of a modular EV charger may warp or be permanently damaged should a module connector be misaligned when an attempt is made to couple it to a backplane connector. The consequences of warped or damaged power connector include reduced efficiency, affected functionality, decreased lifespan, and the possibility of explosion and fire.

A modular electronics assembly such as a modular EV charger should permit the replacement of modules with minimal time, cost, and field expertise.

It is an object of the present invention to provide a modular electronics assembly that addresses at least one of the problems that have been discussed.

### SUMMARY OF INVENTION

In a first aspect, the invention provides a modular electronics assembly comprising:
removable electronic modules each comprising a module housing containing electronic circuitry and bearing a module electrical connector coupled to said circuitry each removable electronic module having a first alignment formation;
an enclosure having an interior dimensioned to contain the removable electronic modules therein, the enclosure including,
   one or more enclosure electrical connectors corresponding to one or more of the module electrical connectors for establishing a connection therewith,
   guide members extending into the interior of the enclosure for positioning respective ones of the module housings relative to the enclosure electrical connectors;
   second alignment formations each arranged to cooperate with a respective first alignment formation of the removable electronic modules for aligning respective module electrical connectors with respective enclosure electrical connectors to thereby establish the connection therebetween;
wherein the first alignment formations are positioned on the module housings to register with respective of the second alignment formations upon the module housings abutting respective of the guide members.

In an embodiment the guide members comprise shelves for supporting the removable electronic modules.

In an embodiment the shelves comprise a horizontal support portion and a vertical backing portion.

In an embodiment the vertical backing portion may be fixed to a rear of the enclosure.

In an embodiment the guide members further comprise an angled or “bevelled” portion for directing the module housing across the shelf to thereby register the first alignment formation with the second alignment formation. Herein the term “register” is used to mean “a condition of correct alignment or proper relative position”.

In an embodiment the bevelled portion may comprise part of the backing portion wherein the bevelled portion is at right angles to the support portion.

In an embodiment the modular electronics assembly includes one or more backplanes wherein one or more of the enclosure electrical connectors are located on the one or more backplanes.

In an embodiment the first alignment formation comprises an opening through the module housing.

In an embodiment the second alignment formations comprise elongate alignment members extending from a portion of the enclosure.

In an embodiment the at least one backplane is formed with alignment member openings wherein the elongate alignment members extend through the alignment member openings.

In an embodiment the enclosure includes a guard member arranged to guard an operator from inadvertently touching the backplane subsequent to removal of the removable electronic modules.

In an embodiment the elongate alignment members extend from a casing of the enclosure.

In an embodiment each elongate alignment member includes a chamfered, fileted, conical or frustoconical head portion to assist in moving respective alignment openings over respective elongate alignment members.

In an embodiment one or more of the removable electronic modules include one or more conduits therethrough for carrying liquid for liquid cooling of the electronic circuitry.

In an embodiment the one or more of the removable electronic modules include dry break disconnect couplers at ends of the one or more conduits for sealing the conduits upon removing the removable electronic modules from the enclosure.

In an embodiment the enclosure comprises a rear wall, top wall, bottom wall and opposed side walls defining the interior.

In an embodiment the enclosure further comprises a door hinged along one of said walls for closing the interior.

In an embodiment the enclosure further comprises a locking assembly for locking the door in a closed position.

In an embodiment the enclosure further comprises a cover for the locking assembly for preventing tampering therewith.

In an embodiment the cover comprises a wing hinged along one of said sides of the enclosure.

In an embodiment the cover is fastened over the locking assembly with a plurality of fasteners.

In an embodiment the locking assembly is arranged for locking with a padlock locatable beneath the cover.

In an embodiment the modular electronics assembly further includes a heat exchanger assembly.

In an embodiment the enclosure is mounted atop the heat exchanger assembly.

In an embodiment the modular electronics assembly further includes an input circuit assembly in electrical communication with the removable electronic modules via the backplane.

In an embodiment the modular electronics assembly further includes an output circuit assembly in electrical communication with the removable electronic modules.

In an embodiment the output circuit assembly is mounted in an upper portion of the enclosure.

In an embodiment the input circuit assembly is mounted in a lower portion of the enclosure and is adjacent the heat exchanger.

In an embodiment the modular electronics assembly includes a connector for an electric vehicle charger cable that is coupled to the output circuit.

In an embodiment the connector for the electric vehicle charger cable is accessible through an opening formed in the cover.

In an embodiment the modular electronics assembly includes a core control unit.

In an embodiment the core control unit is fitted to the door.

In an embodiment the modular electronics assembly includes a credit card reader.

In an embodiment the credit card reader is fitted to the door.

In an embodiment the modular electronics assembly includes a human machine interface.

In an embodiment the human machine interface is fitted to the door.

In an embodiment the door is formed with an opening that is covered by a membrane.

In an embodiment the membrane is located adjacent the input circuit assembly.

According to a further aspect there is provided a modular electronics assembly comprising removable electronic modules and a housing configured to contain the removable electronic modules wherein corresponding alignment features and electrical connectors are borne on the electronic modules and on one or more portions of a backplane fast with the enclosure.

According to another aspect there is provided a modular electronics assembly comprising one, or more features, singularly or in combination, said one or more features being disclosed in the foregoing and/or in the following detailed description. For example, the one or more features may comprise features of a locking assembly and/or features of a door and/or features of an alignment arrangement for aligning module electrical connectors of removable electronic modules with enclosure electrical connectors for establishing an electrical connection therebetween.

### BRIEF DESCRIPTION OF THE DRAWINGS

Preferred features, embodiments and variations of the invention may be discerned from the following Detailed Description which provides sufficient information for those skilled in the art to perform the invention. The Detailed Description is not to be regarded as limiting the scope of the preceding Summary of the Invention in any way. The Detailed Description will make reference to a number of drawings as follows:

FIG. 1 a modular electronics assembly in the form of a modular electric vehicle charger shown in an opened configuration.

FIG. 1A is a view of the modular electronics assembly of FIG. 1 depicted partially exploded wherein the removable electronic modules and various panels are shown detached.

FIG. 2 is a view of electronic modules of the modular electronics assembly of

FIG. 3 is a view of an interior of an enclosure of the modular electronics assembly of FIG. 1 with the removable electronic modules removed.

FIG. 4 is a detail of an end of an alignment pin.

FIG. 5 is a front partial view of the modular electronics assembly showing a single modular electronics assembly installed within the enclosure.

### DETAILED DESCRIPTION OF PREFERRED EMBODIMENTS

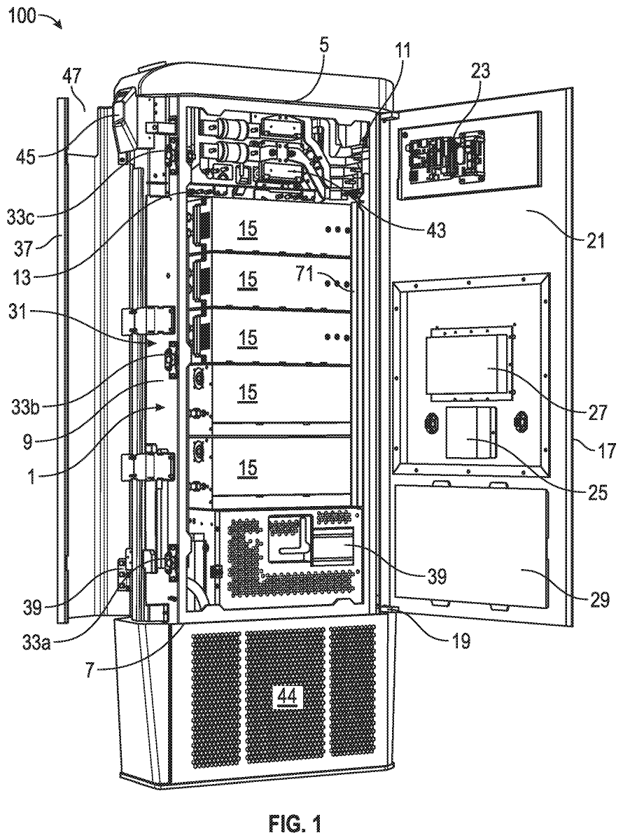

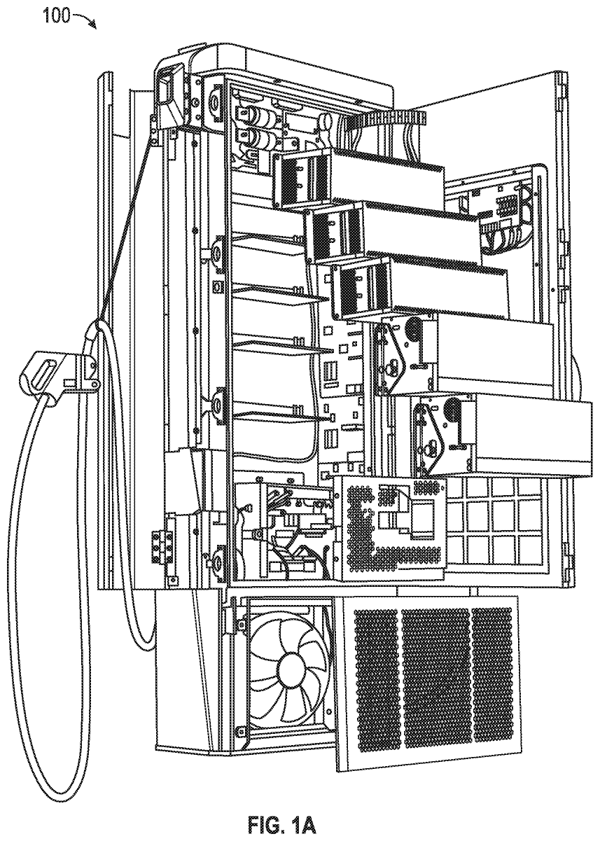

FIGS. 1 to 5 illustrate a modular electronics assembly in the form of a modular electric vehicle charger 100 according to a preferred embodiment of the present invention.

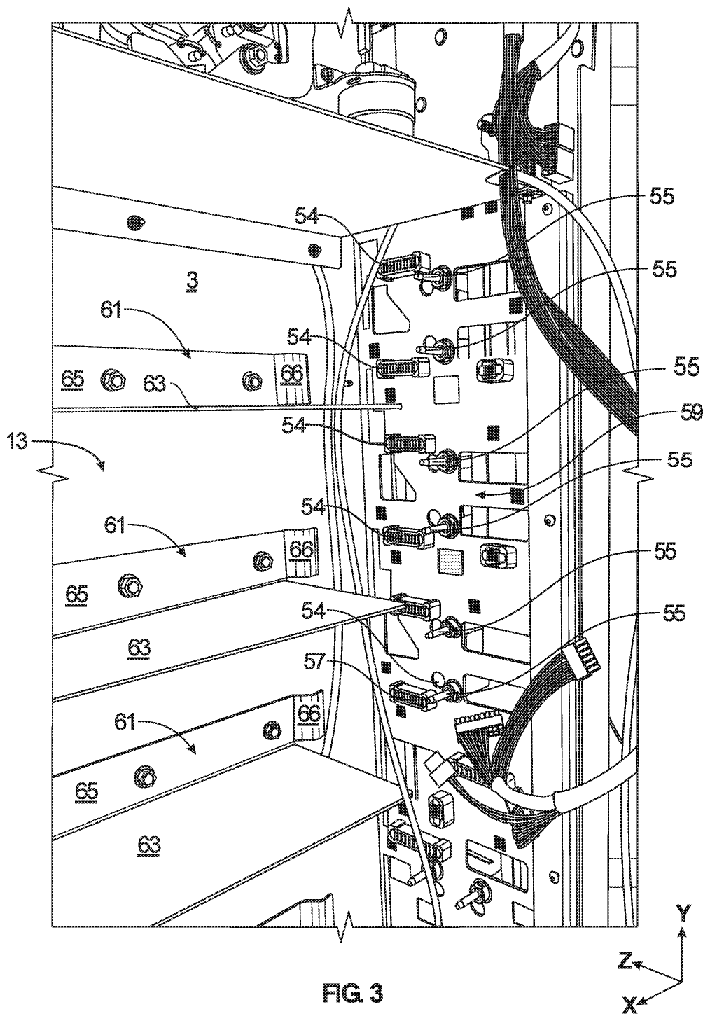

FIG. 1 shows the modular electric vehicle charger 100 which includes an enclosure 1 that is comprised of a rear wall 3 (FIG. 3), top wall 5, bottom wall 7, and left-hand side wall 9 and right-hand side wall 11, which together form a casing that defines an interior 13 (FIG. 3) of the enclosure. As will be discussed the interior 13 of the enclosure houses a number of removable electronic modules 15 of the EV charger 100 which may be removed from the enclosure as illustrated in FIG. 1A. The enclosure 1 also includes a door 17 that is connected by hinges 19 to the right-hand side wall 11 for closing the interior 13 and covering the removable electronic modules 15. In FIG. 1 the door 17 is shown open so that an inner side 21 of the door 17 is visible. Fitted to the door 17 are, a number of components and assemblies including a core control unit 23, a credit card reader 25, a human machine interface 27, and a membrane 29, which covers an opening formed through the door 17 to allow gas exchange through the opening whilst filtering out dust.

The enclosure 1 also includes a locking assembly 31 which is arranged along the left-hand side wall 9 and is for locking the door 17 in a closed position. The locking assembly 31 includes hand operated rotary latches 33a, 33b, 33c that engage the door 17 to lock it closed. The locking assembly 31 can then be locked in place with a padlock (not shown). The enclosure has a cover or “wing” 37 which is connected by hinges 39 along the rear of the left-hand side wall 9 of the enclosure 1 and which can be closed over the locking assembly 31 for preventing tampering. The cover 37 is fastened over the locking assembly, including the padlock, with a plurality of fasteners such as tamperproof Allen head screws.

An input circuit assembly 39 is located in the interior 13 of the enclosure 1 below the removable electronic modules 15. As will be discussed shortly the input circuit assembly 39 and the various removable electronic modules 15 are interconnected by a backplane 59 which is illustrated in FIG. 3. The backplane 59 includes one or more PCBs and may also include bus bars that locate between the one or more PCBs and the enclosure.

The enclosure 1 is mounted atop a heat exchanger assembly 44 which assists in cooling portions of the modular electronics assembly and in particular the input circuit assembly 39. The bottom wall 7 of the enclosure 1 may comprise an upper wall of the heat exchanger assembly in some embodiments.

The EV charger 100 also includes an output circuit assembly 43 in electrical communication with the removable electronic modules 15. The output circuit assembly 43 is mounted in an upper portion of the enclosure.

An electric vehicle charging connector 45 is provided that is fitted to the left-hand side wall 9 of the enclosure 1 and which is coupled to the output circuit 43. The electric vehicle charging connector 45 is for receiving a complementary connector of an electric vehicle charging cable for an electric vehicle. The electric vehicle charging connector is accessible through an opening 47 formed in the cover 37 when the cover 37 is in the closed position.

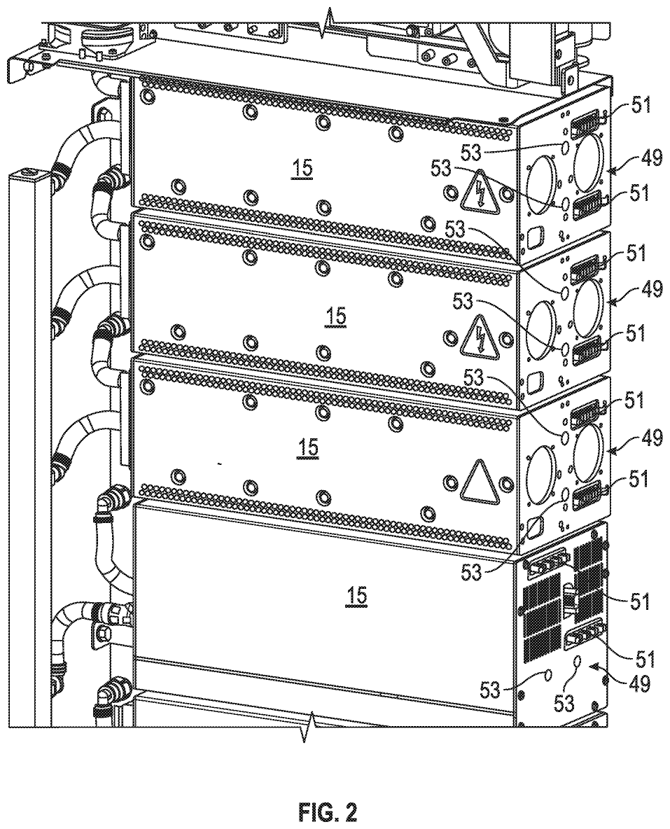

Referring now to FIG. 2, the removable electronic modules 15 each comprise a module housing 49 which contains electronic circuitry. Each module housing 49 bears at least one module electrical connector 51 that is coupled to the electronic circuitry within the housing 49. Each removable electronic module 15 has at least one first alignment formation in the form of alignment hole 53 for cooperating with a respective second alignment formation, in the form of alignment pin 55, that is fast with, (i.e., fixed directly to or fixed relative, though indirectly to), the enclosure 1 in order to align a module connector 51 of the removable electronic module 15 with an enclosure connector 57.

It will be observed that the module connectors 51 are each distanced from their adjacent alignment holes 53 a distance that corresponds to that of the enclosure connectors 57 from their adjacent alignment pins 55. Consequently, aligning alignment pins with corresponding alignment holes causes the enclosure connectors to align with (and thus to register with) the corresponding module connectors.

In the presently described embodiment the alignment pins 55 extend into the interior 13 of the enclosure 1 from the enclosure 1. Accordingly, the interior 13 of the enclosure 1 is dimensioned to contain the removable electronic modules 15 and also includes one or more enclosure electrical connectors 57 corresponding to one or more of the module electrical connectors 51 for establishing a connection therewith. The enclosure electrical connectors 57 are preferably located on one or more backplanes 59 that are located in the interior of the enclosure 1 and in the present embodiment are parallel to the right-hand side wall 11 of the enclosure 1.

The enclosure 1 includes guide members in the form of shelves 61 that extend into the interior 13 of the enclosure 1. The shelves 61 include a horizontal support portion 63 and a vertical backing portion 65. The shelves 61 are for guiding or directing respective ones of the module housings 15 toward the enclosure electrical connectors 57. As previously mentioned, the enclosure 1 includes second alignment formations in the form of elongate alignment members or alignment pins 55, each arranged to cooperate with the respective first alignment formations, in the form of alignment holes 53, of the removable electronic modules 15 in order to align respective module electrical connectors 51 with respective enclosure electrical connectors 57 to thereby establish the connection therebetween.

The first alignment formations in the form of the alignment holes 53 are positioned on the module housings 15 so that they may be brought to register with respective of the alignment pins 55 upon the module housings abutting, for example resting upon, respective of the guide members in the form of the shelves 61.

The shelves 61 include a backing portion 65 which fastens to the rear wall 3 of the enclosure 1 and which includes an angled or beveled portion 66 that slopes into the interior and which acts to translate or direct the module housing 15 across the shelf, i.e. away from the rear wall 3, in order to bring each alignment hole 53 on the module housing 15 into registration with a respective alignment pin 55.

In an embodiment the beveled portion 66 is disposed at right angles to the support portion 63 of the shelf and extends from the backing portion at an angle of about thirty degrees thereto.

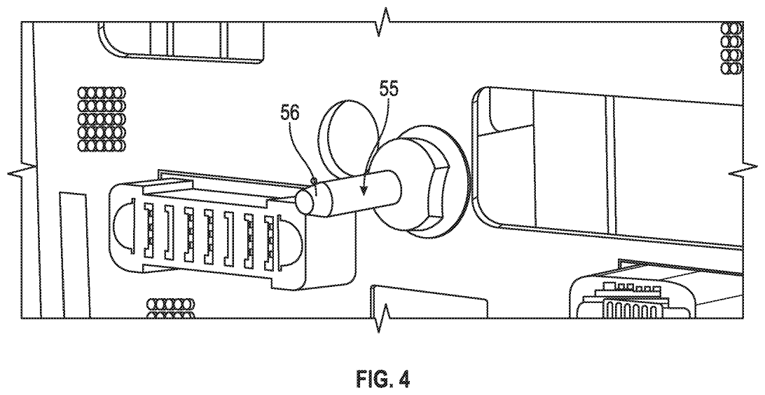

As may be seen in FIG. 3, the alignment pins 55 extend from a portion of the enclosure 1 such as the right-hand side wall 11 in the present embodiment. The backplane 59 is formed with alignment member openings in the form of holes 54 through which the alignment pins 55 extend once the removable electronic module 15 is installed. One such hole 54 (unpopulated) is identified in FIG. 3. Each elongate alignment member 55 may include a chamfered, fileted, conical or frustoconical head portion 56 (FIG. 4) to assist in moving respective alignment holes 53 over respective elongate alignment members 55.

The enclosure 1 also includes a guard member 71 (FIG. 1) or “stopper” that is arranged to guard an operator from inadvertently touching the backplane 59 subsequent to removal of the removable electronic modules 15. There is a sufficiently tight fit between the module, enclosure and guard member 71 such that there are no holes large enough for the operator's fingers to pass between and inadvertently touch the HV bus bars and PCB.

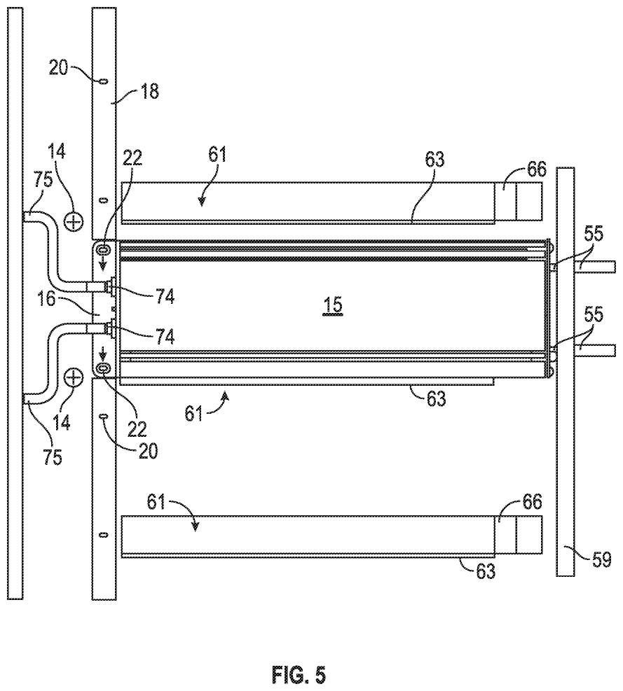

One or more of the removable electronic modules 15 include one or more conduits in the form of internal liquid cooling pipes which are arranged in each module for liquid cooling of the internal electronic circuitry therein. The internal liquid cooling pipes connect to external cooling pipes 75 by means of dry break disconnect couplers 74 (FIG. 5), which are coupled to ends of the internal liquid cooling pipes. The dry break disconnect couplers 74 are arranged to seal the internal liquid cooling pipes upon disconnection from the external cooling pipes 75 and removal of the removable electronic modules 15 from the enclosure 1. A major downside of liquid cooling is the necessity to drain the liquid cooling pipes for service. However, by using dry break disconnect couplers 74 no drainage is required and thus the removal of the removable electronic modules 15 is straightforward and safe. Furthermore, replacement modules come pre-loaded with coolant so no additional coolant is needed.

In the present embodiment the removable electronic modules 15 comprise AC→DC and DC→DC modules, which are the parts of the EV charger 100 that require service most often. As the upgradeability of the EV charger 100 relies on replacing the AC→DC and DC→DC modules with their improved versions as they are developed, it is beneficial that they are easy to remove. The efficient removal and replacement of removable electronic modules 15, such as AC→DC and DC→DC modules is fundamentally enabled by the cooperative alignment holes 53 and alignment pins 55. The alignment pins 55 extend from the charger casing, e.g. the inner side of the left-hand side wall 71, through the backplane 59, and into the corresponding alignment holes 53 in each respective removable electronic module 15. The alignment pins 55, cooperating with the alignment holes 53, rather than the mating of the enclosure electrical connectors 57 with the module connectors 51, mechanically stabilize and align the modules 15 with the backplane 59, thus preventing mechanical overloading and breakage of the enclosure electrical connectors 57 and/or the module connectors 51.

The following steps outline the process of servicing and upgrading one of the removable electronic modules 15 (which in the following is referred to as “module 15” for brevity) of the EV charger 100:

The door 17 of the EV charger 100 is opened by firstly undoing the tamper-proof Allen screws with a corresponding key and then opening the wing 37, unlocking the padlock and turning the rotary latches 33a, 33b, 33c.

The liquid cooling pipes 75 are then disconnected from the module 15.

The module attachment screws 14 are then removed so that the module bracket 16 is freed from attachment to pole 18. Module 15 is then slid along the support portion 63 of the shelf 61 away from the backplane 59, which disconnects the module connectors 51 from the enclosure connectors 57 that are mounted to the backplane 59. Guard member 71 prevents the technician from touching the backplane 59 while the risk of residual electricity subsists. Additionally, the module housings 49 also prevent the technician from directly touching the internal electronic circuitry 28 that may store residual charge.

The module 15 is then lifted from the EV charger 100 in its entirety. Each module 15 is preferably of a weight that can be lifted by a single technician.

The technician can then replace the entire module 15 with a new iteration of the same version, or an upgraded version. As per the process above, the technician can lift the new module 15 on their own, placing it on the horizontal support portion 63 of shelf 61. The shelf 61 serves the purpose of relieving the technician of the weight of the module 15, maintaining the position of the module in the charger, and aligning the module, along the Y axis, with the alignment pins 55 that extrude through the backplane 59.

The technician then pushes the module 15 against the pole 18 (FIG. 5) and the bevel portion 66, which registers alignment holes 53 of the module 15 with the alignment pins 55 along the Z axis (the X Y Z axes referred to herein are indicated in FIG. 3).

The technician then slides the module 15 towards the backplane 59 into the pins along the X axis. The alignment pins 55 cooperate with the sides of the holes 53 to mechanically alter the module's X, Y and Z axis positioning to precisely alignment the module connectors 51 with the enclosure connectors 57.

The technician then firmly presses the module 15 into the backplane along the X axis, lining up the screw holes 20 on the pole 18 with the screw holes 22 on bracket 16 of the module 15, and screwing module attachment screws 14 into the pole screw holes 20, which establishes a connection between the module connectors 51 and the enclosure connectors 57 connection along X axis and ensures the module 15 is securely and safely connected to the backplane 59.

On the left side of the EV charger 100, the technician then has enough space to bend external liquid cooling pipes 75 and connect them to the dry disconnect couplers 74 of the module 15.

In compliance with the statute, the invention has been described in language more or less specific to structural or methodical features.

The term “comprises” and its variations, such as “comprising” and “comprised of” is used throughout in an inclusive sense and not to the exclusion of any additional features.

It is to be understood that the invention is not limited to specific features shown or described since the means herein described comprises preferred forms of putting the invention into effect.

The invention is, therefore, claimed in any of its forms or modifications within the proper scope of the appended claims appropriately interpreted by those skilled in the art.

1. A modular electronics assembly comprising:
removable electronic modules each comprising a module housing containing electronic circuitry and bearing a module electrical connector coupled to the electronic circuitry each removable electronic module having a first alignment formation;
an enclosure having an interior dimensioned to contain the removable electronic modules therein, the enclosure including,
one or more enclosure electrical connectors corresponding to one or more of the module electrical connectors for establishing a connection therewith,
guide members extending into the interior of the enclosure for guiding respective ones of the module housings toward the enclosure electrical connectors;
second alignment formations each arranged to cooperate with a respective first alignment formation of the first alignment formations of the removable electronic modules for aligning respective module electrical connectors with respective enclosure electrical connectors to thereby establish the connection therebetween;
wherein the first alignment formations are positioned on the module housings to register with respective of the second alignment formations upon the module housings abutting respective of the guide members.

2. The modular electronics assembly of claim 1, wherein the guide members comprise shelves arranged to support the removable electronic modules.

3. The modular electronics assembly of claim 2, wherein the shelves comprise a horizontal support portion and a vertical backing portion.

4. The modular electronics assembly of claim 3, wherein the vertical backing portion is fixed to a rear of the enclosure.

5. The modular electronics assembly of claim 4, wherein the guide members further comprise a beveled portion configured to direct the module housings across the shelves to thereby register the first alignment formation with the second alignment formation.

6. The modular electronics assembly of claim 5, wherein the beveled portion comprises part of the backing portion wherein the beveled portion is at right angles to the horizontal support portion.

7. The modular electronics assembly of claim 1, wherein the modular electronics assembly includes at least one backplane wherein one or more of the enclosure electrical connectors are located on the at least one backplane.

8. The modular electronics assembly of claim 7, wherein the first alignment formation comprises an opening through the module housing.

9. The modular electronics assembly of claim 8, wherein the second alignment formations comprise elongate alignment members extending from a portion of the enclosure and wherein the at least one backplane is formed with alignment member openings wherein the elongate alignment members extend through the alignment member openings.

10. (canceled)

11. The modular electronics assembly of claim 7 the enclosure includes a guard member arranged to guard an operator from inadvertently touching the at least one backplane.

12. The modular electronics assembly of claim 9, wherein the elongate alignment members extend from a casing of the enclosure and wherein each elongate alignment member includes a chamfered, fileted, conical or frustoconical head portion to assist in moving respective alignment openings over respective elongate alignment members.

13. (canceled)

14. The modular electronics assembly of claim 1, wherein one or more of the removable electronic modules include one or more conduits therethrough for carrying liquid for cooling by liquid of the electronic circuitry.

15. The modular electronics assembly of claim 14, wherein the one or more of the removable electronic modules include dry break disconnect couplers at ends of the one or more conduits for sealing the conduits upon removing the removable electronic modules from the enclosure.

16. (canceled)

17. (canceled)

18. (canceled)

19. (canceled)

20. (canceled)

21. (canceled)

22. (canceled)

23. The modular electronics assembly of claim 1, further comprising a heat exchanger assembly and wherein the enclosure is mounted atop the heat exchanger assembly.

24. (canceled)

25. The modular electronics assembly of claim 23, including an input circuit assembly in electrical communication with the removable electronic modules via the at least one backplane and wherein the input circuit assembly is mounted in a lower portion of the enclosure and is adjacent the heat exchanger.

26. (canceled)

27. The modular electronics assembly of claim 7, including an output circuit assembly in electrical communication with the removable electronic modules and wherein the output circuit assembly is mounted in an upper portion of the enclosure and further including a connector for an electric vehicle charger cable that is coupled to the output circuit assembly, the connector for the electric vehicle charger cable accessible through an opening formed in the cover.

28. (canceled)

29. (canceled)

30. (canceled)

31. The modular electronics assembly of claim 7, including a core control unit.

32. (canceled)

33. The modular electronics assembly of claim 7, including a credit card reader.

34. (canceled)

35. The modular electronics assembly of claim 7, including a human machine interface.

36. (canceled)

37. The modular electronics assembly of claim 25, wherein the door is formed with an opening that is covered by a membrane located adjacent the input circuit assembly.

38. (canceled)
